(19) United States
(12) Patent Application Publication
(10) Pub. No.: US 2009/0233105 A1
(43) Pub. Date: Sep. 17, 2009

(54) Composite coatings comprising hollow and/or shell like metal oxide particles deposited via combustion deposition

(76) Inventors: Michael P. Remington, JR., Toledo, OH (US); David D. McLean, Hazel Park, MI (US)

Correspondence Address: NIXON & VANDERHYE, PC, 901 NORTH GLEBE ROAD, 11TH FLOOR, ARLINGTON, VA, 22203, US

(21) Appl. No.: 12/149,460

(22) Filed: May 1, 2008

Related U.S. Application Data
(63) Continuation-in-part of application No. 12/076,100, filed on Mar. 13, 2008.
Application No. 12/076,100 is a continuation-in-part of application No. 12/076,101, filed on Mar. 13, 2008.

(51) Int. Cl. C23C 16/06; B32B 17/06; B32B 15/04

(52) U.S. Cl. 428/432; 427/255.32

(57) ABSTRACT

Certain example embodiments relate to the combustion deposition depositing of coatings comprising metal oxide matrices loaded with hollow metal oxide particles. The hollow metal oxide particles may be produced by combusting an emulsion including an aqueous phase and an oil phase, and an optional surfactant. The aqueous and/or oil phase may include a first metal oxide precursor. A second metal oxide precursor may be combusted in addition to the emulsion to produce a dense binder layer, acting as a “glue” to hold the hollow particles together. The matrix and the hollow particles comprising the coating may be of or include the same metal or a different metal. In certain example embodiments, the microstructure of the final deposited coating may resemble the microstructure of coatings produced by wet chemical (e.g., sol gel) techniques.

### FIELD OF THE INVENTION

This application is a continuation-in-part (CIP) of application Ser. No. 12/076,100, filed Mar. 13, 2008 and application Ser. No. 12/076,101, filed Mar. 13, 2008, the entire contents of each of which are hereby incorporated herein by reference.

### FIELD OF THE INVENTION

Certain example embodiments of this invention relate to the deposition of metal oxide coatings onto substrates via combustion deposition. More particularly, certain example embodiments relate to the combustion deposition depositing of coatings comprising metal oxide matrices loaded with hollow metal oxide particles. The matrix and the hollow particles comprising the coating may be of or include the same metal or a different metal. In certain example embodiments, the microstructure of the final deposited coating may resemble the microstructure of coatings produced by wet chemical (e.g., sol gel) techniques. In certain example embodiments, the composite coating may be hydrophilic and/or photo-catalytic.

### BACKGROUND AND SUMMARY OF EXAMPLE EMBODIMENTS OF THE INVENTION

Combustion chemical vapor deposition (combustion CVD) is a relatively new technique for the growth of coatings. Combustion CVD is described, for example, in U.S. Pat. Nos. 5,652,021; 5,858,465; and 6,013,318, each of which is hereby incorporated herein by reference in its entirety.

Conventionally, in combustion CVD, precursors are dissolved in a flammable solvent and the solution is delivered to the burner where it is ignited to give a flame. Such precursors may be vapor or liquid and fed to a self-sustaining flame or used as the fuel source. A substrate is then passed under the flame to deposit a coating.

There are several advantages of combustion CVD over traditional pyrolytic deposition techniques (such as CVD, spray and sol-gel, etc.). One advantage is that the energy required for the deposition is provided by the flame. A benefit of this feature is that the substrate typically does not need to be heated to temperatures required to activate the conversion of the precursor to the deposited material (e.g., a metal oxide). Also, a curing step (typically required for spray and sol-gel techniques) typically is not required. Another advantage is that combustion CVD techniques do not necessarily require volatile precursors. If a solution of the precursor can be atomized/nebulized sufficiently (e.g., to produce droplets and/or particles of sufficiently small size), the atomized solution will behave essentially as a gas and can be transferred to the flame without requiring an appreciable vapor pressure from the precursor of interest.

It will be appreciated that combustion deposition techniques may be used to deposit metal oxide coatings (e.g., single-layer anti-reflective coatings) on glass substrates, for example, to alter the optical and other properties of the glass substrates (e.g., to increase visible transmission). To this end, conventional combustion deposition techniques were used by the inventors of the instant application to deposit a single layer anti-reflective (SLAR) film of silicon oxide (e.g., SiO₂ or other suitable stoichiometry) on a glass substrate. The attempt sought to achieve an increase in light transmission in the visible spectrum (e.g., wavelengths of from about 400-700 nm) over clear float glass with an application of the film on one or both sides of a glass substrate. In addition, increases in light transmission for wavelengths greater the 700 nm are also achievable and also may be desirable for certain product applications, such as, for example, photovoltaic solar cells. The clear float glass used in connection with the description herein is a low-iron glass known as “Extra Clear,” which has a visible transmission typically in the range of 90.3% to about 91.0%. Of course, the examples described herein are not limited to this particular type of glass, or any glass with this particular visible transmission.

The combustion deposition development work was performed using a conventional linear burner. As is conventional, the linear burner was fueled by a premixed combustion gas comprising propane and air. It is, of course, possible to use other combustion gases such as, for example, natural gas, butane, etc. The standard operating window for the linear burner involves air flow rates of between about 150 and 300 standard liters per minute (SLM), using air-to-propane ratios of about 15 to 25. Successful coatings require controlling the burner-to-lite distance to between about 5-50 mm when a linear burner is used.

Typical process conditions for successful films used a burner air flow of about 225 SLM, an air-to-propane ratio of about 19, a burner-to-lite distance of 35 mm, and a glass substrate velocity of about 50 mm/sec.

FIG. 1 is a simplified view of an apparatus 100 including a linear burner used to carry out combustion deposition. A combustion gas 102 (e.g., a propane air combustion gas) is fed into the apparatus 100, as is a suitable precursor 104 (e.g., via insertion mechanism 106, examples of which are discussed in greater detail below). Precursor nebulization (108) and at least partial precursor evaporation (110) occur within the apparatus 100 and also may occur external to the apparatus 100, as well. The precursor could also have been delivered as a vapor reducing or even eliminating the need for nebulization The flame 18 may be thought of as including multiple areas. Such areas correspond to chemical reaction area 112 (e.g., where reduction, oxidation, and/or the like may occur), nucleation area 114, coagulation area 116, and agglomeration area 118. Of course, it will be appreciated that such example areas are not discrete and that one or more of the above processes may begin, continue, and/or end throughout one or more of the other areas.

Particulate matter begins forming within the flame 18 and moves downward towards the surface 26 of the substrate 22 to be coated, resulting in film growth 120. As will be appreciated from FIG. 1, the combusted material comprises non-vaporized material (e.g., particulate matter), which is also at least partially in particulate form when coming into contact with the substrate 22. To deposit the coating, the substrate 22 may be moved (e.g., in the direction of the velocity vector). Of course, it will be appreciated that the present invention is not limited to any particular velocity vector, and that other example embodiments may involve the use of multiple apparatuses 100 for coating different portions of the substrate 22, may involve moving a single apparatus 100 while keeping the substrate in a fixed position, etc. The burner 110 is about 5-50 mm from the surface 26 of the substrate 22 to be coated.

Using the above techniques, the inventors of the instant application were able to produce coatings that provided a transmission gain of 1.96% or 1.96 percentage points over the visible spectrum when coated on a single side of clear float glass. The transmission gain may be attributable in part to some combination of surface roughness increases and air incorporation in the film that yields a lower effective index of refraction.

Although a percent change in Tᵥᵢₛ gain of about 2% is advantageous, further improvements are still possible. For example, optical modeling of these layers suggests that an index of refraction of about 1.33 for coatings that are about 100 nm thick should yield a transmission gain of about 3.0-3.5% or about 3.0-3.5 percentage points. The index of refraction of bulk density (e.g., no or substantially no air incorporation) silicon dioxide is nominally between about 1.45-1.5.

Furthermore, it would be desirable to approximate the properties obtained via sol-gel techniques. Sol-gel derived coatings of metal oxides (e.g., of silicon oxide) have been found to provide an increase in transmission of nominally about 3.5% over the visible spectrum when coated on a single side of clear float glass. For example, sol-gel coatings having a silicon oxide (e.g., SiO₂ or other suitable stoichiometry) based matrix which had silica nano-particles embedded therein were produced. The interaction of the silicon oxide matrix with the nano-particles produced a microstructure that gave rise to the coating's excellent AR properties.

Thus, it will be appreciated that there is a need in the art for improved techniques for depositing metal oxide coatings (e.g., anti-reflective coatings of, for example, silicon oxide) on glass substrates via combustion deposition, for combustion deposition techniques that yield coatings exhibiting properties comparable to those produced by the sol-gel processes noted above, and/or for metal oxide coatings having improved microstructures (e.g., metal oxide coatings having nano-particles embedded therein). It also may be possible to use the techniques described herein as a different method for controlling microstructures, in general.

According to certain example embodiments, to improve the percent change in Tᵥᵢₛ gain beyond the current levels of 1.96%, metal oxide coatings (e.g., silicon oxide coatings) may be produced using techniques that cause the microstructure of the coatings to emulate the microstructures of sol gel deposited coatings. The coatings produced in accordance with certain example embodiments possess an enhanced transmission increase over previously combustion deposition produced single-layer anti-reflective (SLAR or single-layer AR) coatings. This may be accomplished in certain example embodiments by providing intermixed or graded metal oxide coatings through nano-particle matrix loading of metal oxide coatings via combustion deposition. More particularly, it may be accomplished in certain example embodiments by using a precursor and by depositing surface passivated nano-particles from a finely atomized solution or colloid (which may be of or include the same or different metals) that respectively produce small nucleation particle size distributions and nano-particle size distributions to grow a coating where there is an increased number of air gaps with increased particle size, thereby reducing the index of refraction of the coating.

Furthermore, in the synthesis of particles by flame spray pyrolysis, certain process conditions may result in hollow, shell-like, or inhomogeneous particles being produced. In general, these types of particles are considered undesirable byproducts of the flame spray pyrolysis process. However, the inventors of the instant application have realized that incorporating such particles into a coating by embedding and/or implanting them in a matrix or binder coating may result in advantageous optical properties. Indeed, incorporating hollow metal oxide particles into a dense binder layer or matrix may be useful in, for example, anti-reflective products. Although the formation of these kinds of particles is known, and perhaps because the formation of these kinds of particles typically is viewed as an undesirable byproduct, the inventors of the instant application believe that combustion deposited coatings comprising hollow metal oxide particles have yet to be realized.

Thus, it will be appreciated that it would be advantageous to include these hollow metal oxide particles in dense binder layers or matrices in connection with, or separate from, the above-described processes and/or coated articles.

In certain example embodiments of this invention, a method of forming a coating on a glass substrate using combustion deposition is provided. A glass substrate having at least one surface to be coated is provided. A metal oxide based precursor and a metal oxide based nano-particle inclusive solution or colloid to be combusted by a flame are introduced. At least a portion of the precursor and the nano-particle inclusive solution or colloid are combusted to respectively form first and second combusted materials. The first and second combusted materials each comprise non-vaporized material. First and second combusted materials may be deposited at substantially the same time (e.g., using the same burner) or in separate steps (e.g., using multiple burners, a single burner operating with different process conditions, etc.). The glass substrate is provided in an area so that the glass substrate is heated sufficiently to allow the first and second combusted materials to form growths directly or indirectly, on the glass substrate. The first and second combusted materials respectively produce nucleation particle size distributions and nano-particle size distributions in forming the coating. The coating comprises a metal oxide matrix including metal oxide nano-particles embedded therein.

In certain example embodiments, a method of making a coating on a substrate using combustion deposition is provided. A glass substrate having at least one surface to be coated is provided. A metal oxide based precursor and a metal oxide based nano-particle inclusive solution or colloid to be combusted by a flame are introduced. At least a portion of the precursor and the nano-particle inclusive solution or colloid are combusted to respectively form first and second combusted materials. The first and second combusted material each comprise non-vaporized material. The glass substrate is provided in an area so that the glass substrate is heated sufficiently to allow the first and second combusted materials to form growths directly or indirectly, on the glass substrate. The precursor and the nano-particle inclusive solution or colloid respectively produce nucleation particle size distributions and nano-particle size distributions in forming the coating. The precursor and/or the nano-particle inclusive solution or colloid includes silicon oxide (e.g., SiO₂ or other suitable stoichiometry).

In certain example embodiments, a coated article including a coating supported by a glass substrate is provided. A combustion deposition deposited growth is arranged such that the growth comprises a matrix of small dense nucleation particle size distributions embedded with nano-particle size distributions. The nano-particle size distributions are deposited from a nano-particle inclusive solution or colloid. The coating increases visible transmission of the glass substrate by at least about 2.0% when coated on one side thereof.

In certain example embodiments, a method of making a coated article including a coating supported by a glass substrate is provided. A film comprising a metal oxide matrix having nano-particles embedded therein is formed. The metal oxide matrix is formed directly or indirectly on the substrate by combustion deposition depositing, via a precursor, a first combusted material that would produce small nucleation particle size distributions if coated independently while also combustion deposition depositing, via a nano-particle inclusive solution or colloid, in or on the small nucleation particle size distributions, a nano-particle size distribution. The second combusted material may or may not produce large agglomerate nano-particle size distributions if coated independently.

In certain example embodiments of this invention, a method of forming a coating on a glass substrate using combustion deposition is provided. A glass substrate having at least one surface to be coated is provided. An emulsion to be combusted by a flame is introduced (e.g., in the liquid phase via nebulization and/or atomization processes). The emulsion includes at least an aqueous phase and an oil phase. A first metal oxide precursor is contained in the aqueous phase and/or the oil phase of the emulsion. A second metal oxide precursor to be combusted by the flame is introduced. At least a portion of the emulsion is combusted to form a first combusted material. The first combusted material comprises non-vaporized material. At least a portion of the second precursor is combusted to form a second combusted material. The second combusted material comprises non-vaporized material. The glass substrate is provided in an area so that the glass substrate is heated sufficiently to allow the first and second combusted materials to form growths directly or indirectly, on the glass substrate. The coating comprises a metal oxide matrix having at least some hollow and/or shell-like metal oxide particles embedded and/or implanted in a binding layer. The hollow metal oxide particles and the binding layer are respectively produced by the emulsion and second precursor.

In certain example embodiments, a method of making a coated article comprising a coating supported by a substrate using combustion deposition is provided. A glass substrate having at least one surface to be coated is provided. An emulsion to be combusted by a flame is introduced (e.g., in the liquid phase via nebulization and/or atomization processes). The emulsion includes at least an aqueous phase and an oil phase. A first metal oxide precursor is contained in the aqueous phase and/or the oil phase of the emulsion. A second metal oxide precursor to be combusted by the flame is introduced. At least a portion of the emulsion is combusted to form a first combusted material. The first combusted material comprises non-vaporized material. At least a portion of the second precursor is combusted to form a second combusted material. The second combusted material comprises non-vaporized material. The glass substrate is provided in an area so that the glass substrate is heated sufficiently to allow the first and second combusted materials to form growths directly or indirectly, on the glass substrate. The coating comprises a metal oxide matrix having at least some hollow and/or shell-like metal oxide particles embedded and/or implanted in a binding layer. The hollow metal oxide particles and the binding layer are respectively produced by the emulsion and second precursor.

In certain example embodiments, a coated article including a coating supported by a glass substrate is provided. A combustion deposition deposited growth is grown such that the growth comprises a metal oxide matrix including hollow and/or shell-like metal oxide particles embedded and/or implanted within a metal oxide binding layer. The hollow and/or shell-like metal oxide particles are deposited from an atomized emulsion including at least aqueous and oil phases.

In certain example embodiments, a method of making a coated article including a coating supported by a glass substrate is provided. A film comprising a metal oxide matrix having hollow and/or shell-like metal oxide particles embedded and/or implanted therein is formed. The metal oxide matrix is formed directly or indirectly on the substrate by combustion deposition depositing, via an emulsion including a first precursor contained in an aqueous and/or oil phase thereof, a first combusted material so as to deposit the hollow metal oxide particles, while also combustion deposition depositing, via a second metal oxide precursor, a second combusted material that would produce small nucleation particle size distributions if coated independently.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 is a simplified view of an apparatus including a linear burner used to carry out combustion deposition;

FIG. 2 is a simplified view of an illustrative burner system used to carry out combustion deposition in accordance with an example embodiment;

FIG. 3 is a coated article including a coating supported by a substrate in accordance with an example embodiment;

FIG. 4 is an illustrative flowchart illustrating a process for applying a nano-particle loaded metal oxide coating to a glass substrate using combustion deposition in accordance with an example embodiment;

FIG. 5 is an illustrative flowchart illustrating a process for applying a hollow particle inclusive metal oxide coating to a glass substrate using combustion deposition in accordance with an example embodiment; and

FIG. 6 is a coated article including a coating comprising hollow metal oxide particles supported by a substrate in accordance with an example embodiment.

### DETAILED DESCRIPTION OF EXAMPLE EMBODIMENTS OF THE INVENTION

In certain example embodiments of this invention, a method of forming a coating on a glass substrate using combustion deposition is provided. A glass substrate having at least one surface to be coated is provided. An emulsion to be combusted by a flame is introduced. The emulsion includes at least an aqueous phase and an oil phase. A first metal oxide precursor is contained in the aqueous phase and/or the oil phase of the emulsion. A second metal oxide precursor to be combusted by the flame is introduced. At least a portion of the emulsion is combusted to form a first combusted material. The first combusted material comprises non-vaporized material. At least a portion of the second precursor is combusted to form a second combusted material. The second combusted material comprises non-vaporized material. The glass substrate is provided in an area so that the glass substrate is heated sufficiently to allow the first and second combusted materials to form growths directly or indirectly, on the glass substrate. The coating comprises a metal oxide matrix having at least some hollow metal oxide particles embedded and/or implanted in a binding layer. The hollow metal oxide particles and the binding layer are respectively produced by the emulsion and second precursor.

In certain example embodiments, a method of making a coated article comprising a coating supported by a substrate using combustion deposition is provided. A glass substrate having at least one surface to be coated is provided. An emulsion to be combusted by a flame is introduced. The emulsion includes at least an aqueous phase and an oil phase. A first metal oxide precursor is contained in the aqueous phase and/or the oil phase of the emulsion. A second metal oxide precursor to be combusted by the flame is introduced. At least a portion of the emulsion is combusted to form a first combusted material. The first combusted material comprises non-vaporized material. At least a portion of the second precursor is combusted to form a second combusted material. The second combusted material comprises non-vaporized material. The glass substrate is provided in an area so that the glass substrate is heated sufficiently to allow the first and second combusted materials to form growths directly or indirectly, on the glass substrate. The coating comprises a metal oxide matrix having at least some hollow metal oxide particles embedded and/or implanted in a binding layer. The hollow metal oxide particles and the binding layer are respectively produced by the emulsion and second precursor.

In certain example embodiments, a coated article including a coating supported by a glass substrate is provided. A combustion deposition deposited growth is grown such that the growth comprises a metal oxide matrix including hollow metal oxide particles embedded and/or implanted within a metal oxide binding layer. The hollow metal oxide particles are deposited from an atomized emulsion including at least aqueous and oil phases.

In certain example embodiments, a method of making a coated article including a coating supported by a glass substrate is provided. A film comprising a metal oxide matrix having hollow metal oxide particles embedded and/or implanted therein is formed. The metal oxide matrix is formed directly or indirectly on the substrate by combustion deposition depositing, via an emulsion including a first precursor contained in an aqueous and/or oil phase thereof, a first combusted material so as to deposit the hollow metal oxide particles, while also combustion deposition depositing, via a second metal oxide precursor, a second combusted material that would produce small nucleation particle size distributions if coated independently.

In certain example embodiments, to improve the percent change in Tᵥᵢₛ gain beyond the current levels of 1.96%, metal oxide coatings (e.g., silicon oxide coatings) may be produced using techniques that cause the microstructure of the coatings to emulate the microstructures of sol gel deposited coatings. The coatings produced in accordance with certain example embodiments possess an enhanced transmission increase over previously combustion deposition produced single-layer anti-reflective (SLAR or single-layer AR) coatings. This may be accomplished in certain example embodiments by providing intermixed or graded metal oxide coatings through nano-particle matrix loading of metal oxide coatings via combustion deposition. More particularly, it may be accomplished in certain example embodiments by using a precursor and by depositing surface passivated nano-particles from a finely atomized solution or colloid (which may be the same or different precursors) that respectively produce small nucleation particle size distributions and nano-particle size distributions to grow a coating where there is an increased number of air gaps with increased particle size, thereby reducing the index of refraction of the coating.

Certain example embodiments use a burner system that receives a precursor and a finely atomized solution or colloid comprising surface passivated nano-particles provided to the combustion gas stream. The precursor is combusted so as to produce small nucleation particle size distributions growths or films resulting in a dense matrix or binding metal oxide coating, with the small nucleation particle size distributions being preferably less than about 10 nm (e.g., for silicon oxide based coatings). Such particle sizes may be achieved using low concentrations of precursor in the combustion stream. The finely atomized solution or colloid comprising the surface passivated nano-particles is provided to the combustion stream so as to produce a distribution of nano-particles (e.g., in the range of about 10-100 nm, more preferably in the range of about 10-15 nm) that may or may not produce less dense growths or films if coated independently. If coated independently, the nano-particles may or may not result in a film with an index of refraction range of about 1.25-1.42 for silicon oxide based coatings. Such growths or films may be achieved by forming a colloid or solution including about 15-40% nano-particles by weight. In certain example implementations, the process conditions include a flame temperature of between about 1000-1400° C., an air-to-propane ratio of about 15-30, and an air flow rate of between about 100-300 standard liters per minute.

In certain example embodiments, the composite coating may be hydrophilic and/or photo-catalytic.

Silicon oxide (e.g., SiO₂ or other suitable stoichiometry) coatings made in accordance with certain example embodiments may use the precursor hexamethyldisiloxane (HMDSO). Other precursors, such as tetraethylorthosilicate (TEOS), silicon tetrachloride (e.g., SiCl₄ or other suitable stoichiometry), and the like, may be used. Of course, it will be appreciated that other metal oxide precursors may be used, for example, as the invention is not limited to deposition of silicon dioxide coatings.

The resulting coating therefore may contain a metal oxide matrix (e.g., a silicon oxide matrix) with embedded nano-particles. The coating will possess a microstructure similar to that of coatings produced by sol-gel and provide enhanced anti-reflective properties and perhaps enhanced chemical and/or mechanical durability when compared to coatings deposited without the flux of nanoparticles. Such properties may include, for example, reduced reflection and/or increased visible transmission or increased light transmission at higher wavelengths.

It will be appreciated that the precursor and the nano-particles in the solution or colloid may be of or include the same or different metals. It also will be appreciated that is possible to deposit composite films, or films having a matrix of or including a first metal oxide and also having embedded therein nano-particles of a second metal oxide, the second metal oxide being different from the first metal oxide. By way of example, it is possible to include titanium oxide (e.g., TiO₂, titania, or other suitable stoichiometry) nano-particles in a matrix of or including silicon. Such composite coatings advantageously may incorporate the advantages of one or both materials. For example, a silicon dioxide-inclusive matrix including titanium oxide nano-particles embedded therein may provide some of the photocatalytic or self-cleaning properties of conventional titanium oxide coatings, have a more neutral color appearance than conventional titanium oxide coatings, and be less reflective than conventional titanium oxide coatings.

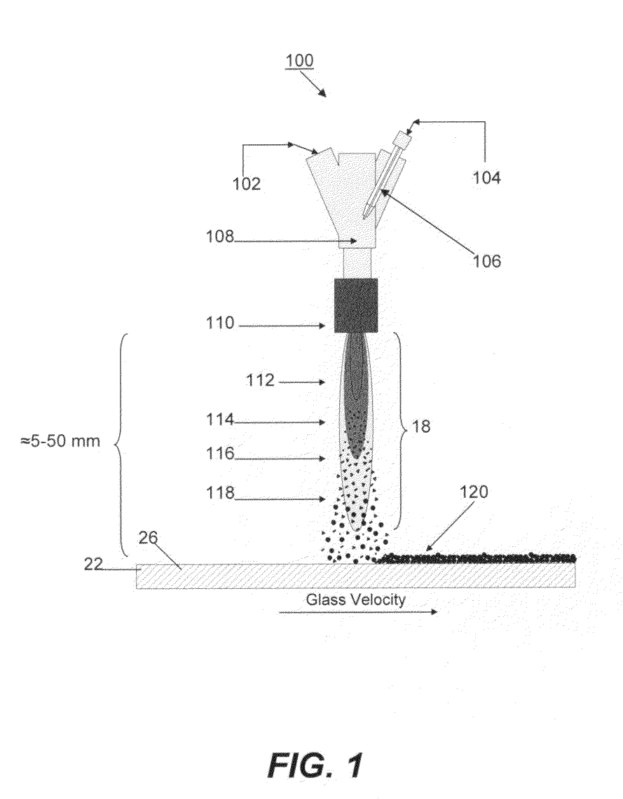

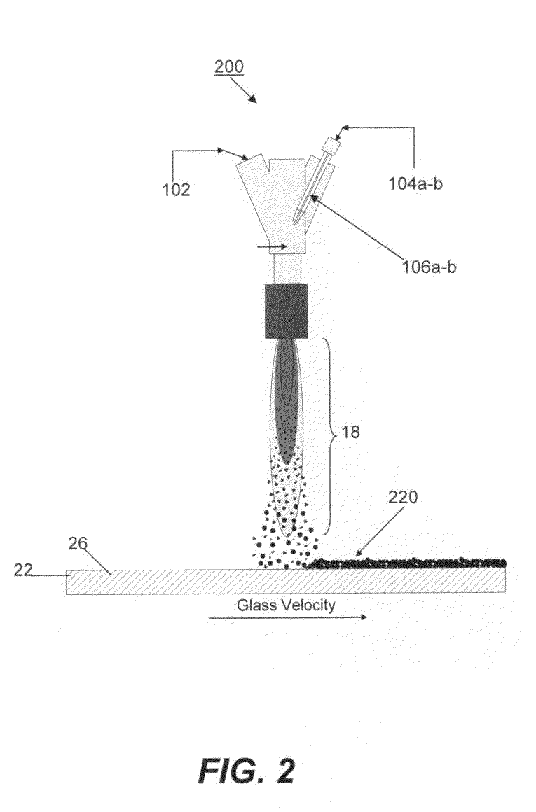

FIG. 2 is a simplified view of an illustrative burner system 200 used to carry out combustion deposition in accordance with an example embodiment. FIG. 2 is similar to FIG. 1, except that the precursor 104a and the finely atomized solution or colloid comprising the surface passivated nano-particles 104b are added to the combustion gas stream 102 via insertion mechanisms 106a-b, respectively. The insertion mechanisms 106a-b may be the same or different insertion system(s), and/or may be provided at the same or different location(s). More particularly, a finely atomized solution or colloid of surface passivated nano-particles is injected into the combustion gas stream. At substantially the same time, a precursor is introduced into the combustion gas stream as a vapor, atomized liquid, or atomized solution. The precursor 104a is selected so that, when combusted by the flame 18, small nucleation particle size distributions are deposited directly or indirectly on the surface to be coated 26 of the substrate 22. The solution or colloid 104b is selected so that, when combusted by the flame 18, nano-particle size distributions also are grown directly or indirectly in or on the small nucleation particle size distributions and/or the substrate. By way of example, if coated independently, the small nucleation particle size distributions may produce a film having an index of refraction of about 1.43-1.46 for silicon oxide based coatings, whereas if coated independently the nano-particle size distributions may or may not produce a film having an index of refraction of about 1.25-1.43 for silicon oxide based coatings. Thus, in certain example embodiments, nano-particles may be loaded into a small nucleation particle matrix when forming the coating. When depositing silicon oxide coatings, the precursor may be hexamethyldisiloxane (HMDSO) or decamethylcyclopentasiloxane (or D5). Other precursors, such as tetraethylorthosilicate (TEOS), silicon tetrachloride (e.g., SiCl₄ or other suitable stoichiometry), and the like, may be used.

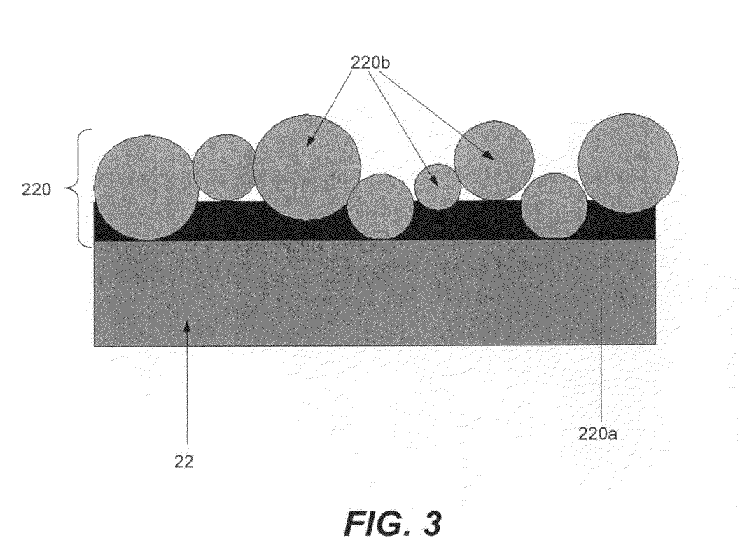

FIG. 3 is a coated article including a coating 220 supported by a substrate 22 in accordance with an example embodiment. The coating 220 is deposited by combustion deposition in one of the above-described and/or other techniques. Also, the metal oxide coating matrices include nano-particles embedded therein via combustion deposition.

Thus, a combustion deposition deposited growth may be arranged such that the growth comprises generally a mixture growth of dense, small particle distributions 220a and nano-particle particle distributions 220b, and the combustion deposition deposited growths 220a-b collectively form a metal oxide matrix including nano-particles, the nano-particles being embedded therein. It will be appreciated that the growths are generally mixtures in the sense that the growths comprising the coating 220 are not completely or entirely discrete. Thus, growths may be “in,” “on” and/or “supported by” other growths in a generally mixed or graded manner, with some of a first or second growth possibly being located partially within a second or first growth, respectively. Furthermore, while the layer mixture or coating 220 is “on” or “supported by” substrate 22 (directly or indirectly), other layer(s) may be provided therebetween. Thus, for example, coating 220 of FIG. 3 may be considered “on” and “supported by” the substrate 22 even if other layer(s) are provided between growth 220a and substrate 22. Moreover, certain growths or layers of coating 220 may be removed in certain embodiments, while others may be added in other embodiments of this invention without departing from the overall spirit of certain embodiments of this invention. It will be appreciated that the refractive index may be adjusted or tuned by varying the number of nano-particles in the matrix and/or by varying the concentration of nano-particles in the colloid or solution.

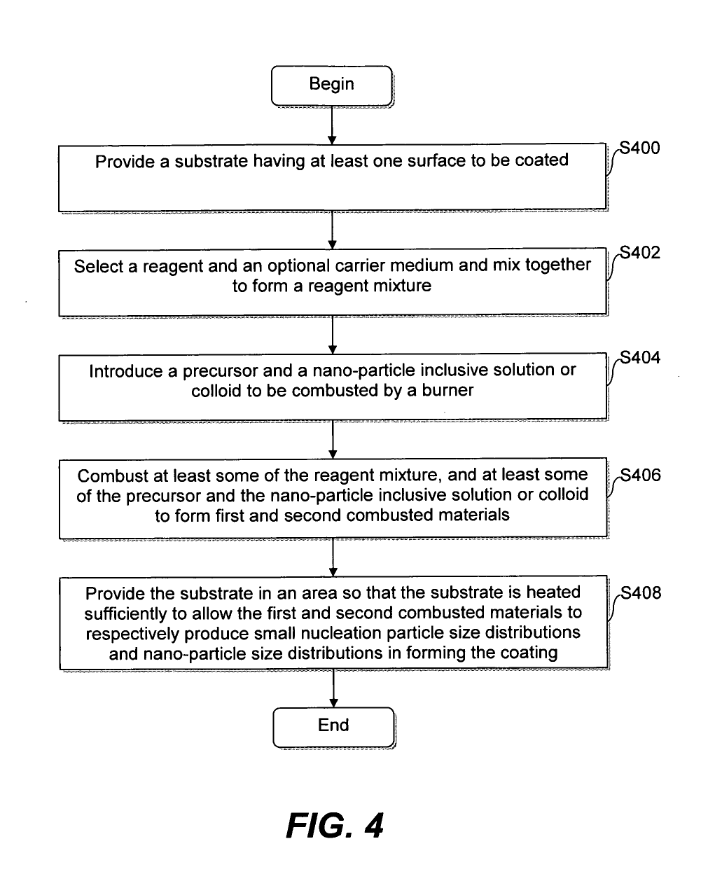

FIG. 4 is an illustrative flowchart illustrating a process for applying an nano-particle loaded metal oxide (e.g., anti-reflective or AR) coating to a glass substrate using combustion deposition in accordance with an example embodiment. In step S400, a substrate (e.g., a glass substrate) having at least one surface to be coated is provided. A reagent (or the combustion gas stream including the fuel source and oxygen) and an optional carrier medium are selected and mixed together to form a reagent mixture in step S402. The reagent is selected so that at least a portion of the reagent forms the coating. A precursor and a nano-particle inclusive solution or colloid to be combusted using a burner are introduced in step S404. In step S406, at least a portion of the reagent mixture, and at least a portion of the precursor and the nano-particle inclusive solution are combusted, thereby respectively forming first and second combusted materials. The precursor and the nano-particle inclusive solution or colloid may be introduced by a number of means. For example, the precursor may be introduced in a vapor state via a bubbler, as large particle droplets via an injector, and/or as small particle droplets via a nebulizer. Also, the nano-particle inclusive solution or colloid may be injected into the combustion stream, for example. In step S408, the substrate is provided in an area so that the substrate is heated sufficiently to allow the first and second combusted materials to respectively produce small, dense nucleation particle size distributions and nano-particle size distributions in forming the coating on the substrate. The small nucleation particle size distributions and/or nano-particle size distributions may be formed either directly or indirectly on the substrate. Also, the small nucleation particle size distributions and/or nano-particle size distributions may be mixed, e.g., as shown in FIG. 3. The small nucleation particle size distributions and/or nano-particle size distributions may be the same or different metal oxides.

Also, optionally, in one or more steps not shown, the opposing surface of the substrate also may be coated. Also optionally, the substrate may be wiped and/or washed, e.g., to remove excess particulate matter deposited thereon.

As noted, the combusted materials may include particulate matter of varying sizes. The particulate matter included in the combusted material may be individual particles or may actually be agglomerations and/or aggregations of multiple particles. Thus, when the size of the particles and/or particulate matter produced is discussed herein, the sizes refer to the total size of either the sizes of the individual particles or the total sizes of the agglomerations. Moreover, the individual particles or particle agglomerations produced may be somewhat differently sized. Accordingly, the sizes specified herein refer to respective size distribution means.

Given the above descriptions, the films of certain example embodiments may be thought of as including a layer of larger particles deposited with a layer of smaller particles (e.g., made using the precursor) acting as a “glue” to hold the larger particles (e.g., made using the finely atomized solution or colloid comprising the surface passivated nano-particles) in place, filling in some gaps, and also sealing in some air. The resulting film therefore may be considered a mixed or graded film, as noted above. Furthermore, in certain example embodiments, the film may get rougher as more is deposited such that it is considered a graded layer.

The nano-particle inclusive solutions or colloids of certain example embodiments may be manufactured or purchased from a commercial source (e.g., from Nissan Chemical, TiOxo Clean, etc.).

Furthermore, as alluded to above, it is possible to deposit coatings comprising hollow, sub-micron particles in connection with certain example embodiments. Similar to the coatings described above, the coatings of certain of these example embodiments may comprise a metal oxide matrix having hollow or shell-like particles implanted and/or embedded therein. These coatings may be composite coatings in certain example implementations (e.g., the coatings may comprise first and second metal oxides which may be the same or different). As described below, they may have a novel structure and/or morphology which, in turn, may lead to corresponding novel physical and/or optical properties. In certain example embodiments, the metal oxide matrix having the hollow or shell-like particles implanted and/or embedded therein may be produced so that the matrix is similar to the above-described matrices and/or so that the hollow or shell-like particles are similar to the above-described nano-particles. The similarities may include, for example, average size distributions, compositions, etc. For example, in certain example implementations, hollow metal oxide particles may be similar to the nano-particle distributions described above, and/or binding layers may be formed from nucleation particle size distributions. Along the same lines, the metal oxide matrix having the hollow or shell-like particles implanted and/or embedded therein may be produced using the above-described and/or similar process conditions.

To achieve such coatings, a finely atomized emulsion of water and oil, with at least one phase including a metal oxie precursor, may be injected into the self-supporting flame of an apparatus used in combustion deposition. In certain example embodiments, the atomization of the emulsion may be accomplished using a nebulizer. The emulsion composition by volume percentage may fall within the following ranges: about 50-80% aqueous, about 10-40% oil, and about 0-10% surfactant. The emulsion composition by volume percentage more preferably will fall within the following ranges: about 60-70% aqueous, about 30-35% oil, and about 0-5% surfactant. However, it will be appreciated that the composition of the emulsion may be varied such that, for example, the volume percents are above, below, or included within the above-noted ranges.

In certain example embodiments, a metal precursor may be a water soluble salt contained in the aqueous phase. However, in certain other example embodiments, a metal precursor may be present in the oil phase. The oil phase may include any suitable organic solvent such as, for example, hexane, pentane, kerosene, toluene, xylene, and/or the like.

In those example embodiments where a surfactant is present, any suitable surfactant may be used. For example, the surfactant may be lauryldimethylamine-oxide (LDAO), sodium dodecylsulfate (SDS), stearyl alcohol, polyethylene glycol monolaurate, polyethylene glycol monooleate and (hexa(2-hydroxy-1,3-propylene glycol) diricinoleate, etc. As is known, surfactants are wetting agents that lower the surface tension of a liquid, allowing easier spreading, and lowering the interfacial tension between two liquids. Surfactants tend to reduce the surface tension of water by adsorbing at the liquid-gas interface. They also tend to reduce the interfacial tension between oil and water by adsorbing at the liquid-liquid interface. Thus, it will be appreciated that a surfactant may be used to help influence the formation of the hollow metal oxide particles, e.g., as described in greater detail below.

The hollow, shell-like particles may be formed by precipitation and decomposition of the metal precursor on the aqueous-oil (e.g., water-oil) interface. That is, the metal precursor will precipitate out of the aqueous or oil phase (depending on where it is initially located in the emulsion). Solids may grow along the aqueous-oil interface as the metal oxide precursor is decomposed. It will be appreciated that growth may potentially occur anywhere the metal precursor is located and the energy is sufficient to promote the reaction. It also will be appreciated that the interface may be used to guide the growth of the sphere(s). These growths may trap air in the particles. It is possible that some water and/or oil also may be trapped within the particles. In some example instances, the shell may not be completely closed, possibly caused by bursting resulting from the evaporation of the water and/or oil. The degree to which this occurs is dependent, at least in part, on how rapidly the particles dry. However, this is not necessarily detrimental to producing a coating with a lower refractive index and therefore is not necessarily to be avoided. Thus, the coatings of certain example embodiments may comprise hollow and/or shell-like spheres that have been fractured or broken as a result of the process. The interface may thus help to guide the growth in relation to the surface tensions of the aqueous and oil phases.

The presence of a surfactant in the emulsion may be used to help adjust the surface tensions or interfacial tension and thus also help to influence the hollow particle formation. In addition, it will be appreciated that components of the aqueous phase (which may contain mostly water in certain example embodiments) and/or the components (e.g., precursor components) of the oil phase may be varied to influence particle properties. For example, the presence of a surfactant and the varying of the components of the aqueous and/or oil phases may be used to affect the microstructures of the ultimate coatings, e.g., by varying the gize(s) and/or composition(s) of the particles produced. Such factors also may be used to adjust the anti-reflective properties of the ultimate coating, e.g., by increasing surface roughness, influencing void size, etc. In certain example embodiments, the hollow particles and the dense binder layer may be sized and/or structured similarly to the coating shown and described in connection with FIG. 3.

A second metal oxide precursor may be introduced to the combustion gas stream as a vapor, atomized liquid, or atomized solution. The second metal oxide precursor may help in forming the binding coating or matrix in which the hollow, shell-like particles may be incorporated. The second metal oxide precursor may be introduced at substantially the same time as the emulsion is introduced in certain example embodiments. In certain other example embodiments, one or more burners may be operated at the same or different process conditions so that the emulsion and the second metal oxide precursor are grown separately. In this latter case, techniques similar to those described in co-pending, commonly assigned application Ser. No. 12/076,101, may be used, in order to grow the hollow particles in situ.

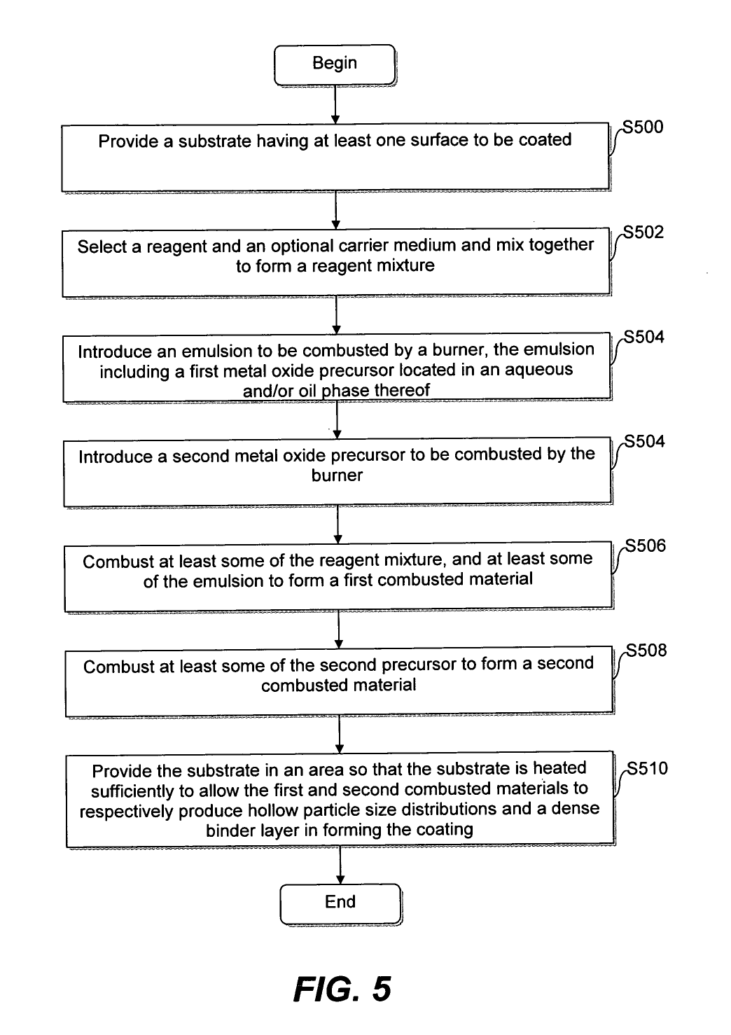

FIG. 5 is an illustrative flowchart illustrating a process for applying a hollow particle inclusive metal oxide coating to a glass substrate using combustion deposition in accordance with an example embodiment. FIG. 5 is somewhat similar to FIG. 4. For example, in step S500, a substrate (e.g., a glass substrate) having at least one surface to be coated is provided. A reagent and an optional carrier medium are selected and mixed together to form a reagent mixture in step S502. The reagent is selected so that at least a portion of the reagent forms the coating. An emulsion to be combusted by a burner is introduced in step S504. The emulsion includes a first metal oxide precursor located in an aqueous and/or oil phase of the emulsion. In step S506, a second metal oxide precursor to be combusted by the burner is introduced. The emulsion and the second precursor may be introduced by a number of means. For example, they may be introduced as large particle droplets via an injector, and/or as small particle droplets via a nebulizer. The second precursor may be introduces in a vapor state via a bubbler. Also, the emulsion and/or second precursor may be injected into the combustion stream, for example.

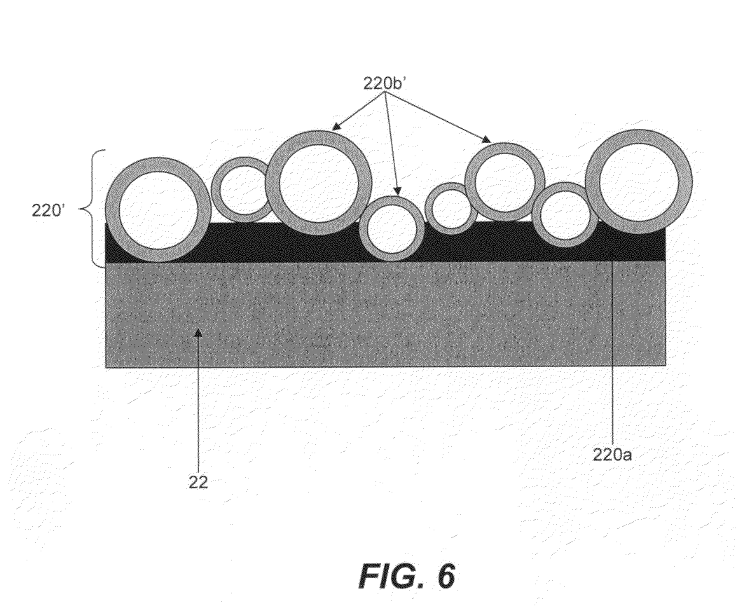

In step S508, at least some of the reagent mixture, and at least some of the emulsion are combusted, thereby forming a first combusted material. In step S510, at least some of the second precursor is combusted to form a second combusted material. In step S510, the substrate is provided in an area so that the substrate is heated sufficiently to allow the first and second combusted materials to respectively produce hollow particle distributions and a dense binder layer in forming the coating on the substrate. It will be appreciated that this may be accomplished substantially at the same time or in discrete steps (e.g., as noted above). The hollow particle distributions and/or the dense binder layer may be formed either directly or indirectly on the substrate. Also, the hollow particle size distributions and/or the dense binder layer may be mixed, e.g., as shown in FIG. 6 (described in greater detail below). The hollow particle distributions and/or the dense binder layer may include the same or different metal oxides.

Also, optionally, in one or more steps not shown, the opposing surface of the substrate also may be coated. Also optionally, the substrate may be wiped and/or washed, e.g., to remove excess particulate matter deposited thereon.

FIG. 6 is a coated article including a coating 220′ comprising hollow metal oxide particles supported by a substrate 22 in accordance with an example embodiment. FIG. 6 is similar to FIG. 3, in that the coating 220′ is deposited by combustion deposition in one of the above-described and/or other techniques. The metal oxide coating 220′ may include hollow particles 220b′ embedded and/or implanted therein via combustion deposition, and these hollow particles 220b′ may be held together by a dense binder layer 220a. The coating 220′ may be a mixture such that the refractive index can be adjusted to the desired level by varying the hollow particle distributions using any number of techniques.

It will be appreciated that the techniques described herein can be applied to a variety of metal oxides, and that the present invention is not limited to any particular type of metal oxide deposition and/or precursor. For example, oxides of the transition metals and lanthanides such as, for example, Y, Ti, Zr, Hf, V, Nb, Ta, Cr, Mo, W, La, Ce, Cr, Mo, W, Mn, Fe, Ru, Co, Ir, Ni, Cu, and main group metals and metalloids such as, for example, Zn, Cd, B, Al, Ga, In, Si, Ge, Sn, Sb and Bi, and mixtures thereof can all be deposited using the techniques of certain example embodiments.

It will be appreciated that the foregoing list is provided by way of example. For example, the metal oxides identified above are provided by way of example. Any suitable stoichiometry similar to the metal oxides identified above may be produced. Additionally, other metal oxides may be deposited, other precursors may be used in connection with these and/or other metal oxide depositions, the precursor delivery techniques may be altered, and/or that other potential uses of such coatings may be possible. Still further, the same or different precursors may be used to deposit the same or different metal oxides for the metal oxide matrix coating and/or the embedded nano-particles.

Also, it will be appreciated that the techniques of the example embodiments described herein may be applied to a variety of products. That is, a variety of products potentially may use these and/or other AR films, depending in part on the level of transmission gain that is obtained. Such potential products include, for example, photovoltaic, green house, sports and roadway lighting, fireplace and oven doors, picture frame glass, etc. Non-AR products also may be produced.

The example embodiments described herein may be used in connection with other types of multiple layer AR coatings, as well. By way of example and without limitation, multiple reagents and/or precursors may be selected to provide coatings comprising multiple layers.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of forming a coating on a glass substrate using combustion deposition, the method comprising:
providing a glass substrate having at least one surface to be coated;
introducing an emulsion to be combusted by a flame, the emulsion including at least an aqueous phase and an oil phase, a first metal oxide precursor being contained in the aqueous phase and/or the oil phase of the emulsion;
introducing a second metal oxide precursor to be combusted by the flame;
combusting at least a portion of the emulsion to form a first combusted material, the first combusted material comprising non-vaporized material;
combusting at least a portion of the second precursor to form a second combusted material, the second combusted material comprising non-vaporized material; and
providing the glass substrate in an area so that the glass substrate is heated sufficiently to allow the first and second combusted materials to form growths directly or indirectly, on the glass substrate,
wherein the coating comprises a metal oxide matrix having at least some hollow metal oxide particles embedded and/or implanted in a binding layer, the hollow metal oxide particles and the binding layer being respectively produced by the emulsion and second precursor.

2. The method of claim 1, further comprising atomizing the emulsion via a nebulizer.

3. The method of claim 1, wherein the emulsion is about 50-80% aqueous by volume, about 10-40% oil by volume, and about 0-10% surfactant by volume.

4. The method of claim 1, wherein the emulsion is about 60-70% aqueous by volume, about 30-35% oil by volume, and about 0-5% surfactant by volume.

5. The method of claim 1, wherein the first metal oxide precursor is a water soluble salt included in the aqueous phase of the emulsion.

6. The method of claim 1, wherein the oil phase includes an organic solvent.

7. The method of claim 6, wherein the organic solvent is at least one of hexane, pentane, kerosene, toluene, and xylene.

8. The method of claim 1, wherein the emulsion includes a surfactant, and
wherein the surfactant is at least one of lauryldimethylamine-oxide (LDAO), sodium dodecylsulfate (SDS), stearyl alcohol, polyethylene glycol monolaurate, polyethylene glycol monooleate and (hexa(2-hydroxy-1,3-propylene glycol)diricinoleate.

9. The method of claim 1, wherein the emulsion and the second metal oxide precursor are introduced into a combustion gas stream at substantially the same time.

10. The method of claim 1, wherein the binding layer has a particle size distribution mean less than about 10 nm.

11. The method of claim 1, wherein the hollow particles have a particle size distribution mean of between about 10-100 nm.

12. The method of claim 1, wherein the coating comprises an oxide of silicon.

13. The method of claim 12, wherein the coating comprises hollow silica particles.

14. The method of claim 12, wherein the coating comprises hollow titania particles.

15. The method of claim 1, further comprising depositing at least one additional coating via combustion deposition on a second surface of the glass substrate.

16. The method of claim 1, wherein the binding layer and the hollow particles respectively comprise first and second metal oxides, the first metal oxide being different from the second metal oxide.

17. The method of claim 1, wherein the coating comprises at least some broken or fractured hollow and/or shell-like metal oxide spheres.

18. A method of making a coated article comprising a coating supported by a substrate using combustion deposition, the method comprising:
providing a glass substrate having at least one surface to be coated;
introducing an emulsion to be combusted by a flame, the emulsion including at least an aqueous phase and an oil phase, a first metal oxide precursor being contained in the aqueous phase and/or the oil phase of the emulsion;
introducing a second metal oxide precursor to be combusted by the flame;
combusting at least a portion of the emulsion to form a first combusted material, the first combusted material comprising non-vaporized material;
combusting at least a portion of the second precursor to form a second combusted material, the second combusted material comprising non-vaporized material; and
providing the glass substrate in an area so that the glass substrate is heated sufficiently to allow the first and second combusted materials to form growths directly or indirectly, on the glass substrate,
wherein the coating comprises a metal oxide matrix having at least some hollow metal oxide particles embedded and/or implanted in a binding layer, the hollow metal oxide particles and the binding layer being respectively produced by the emulsion and second precursor.

19. The method of claim 18, wherein the emulsion is about 50-80% aqueous by volume, about 10-40% oil by volume, and about 0-10% surfactant by volume.

20. The method of claim 18, wherein the emulsion is about 60-70% aqueous by volume, about 30-35% oil by volume, and about 0-5% surfactant by volume.

21. The method of claim 18, wherein the emulsion and the second metal oxide precursor are introduced into a combustion gas stream at substantially the same time.

22. The method of claim 18, wherein the binding layer has a particle size distribution mean less than about 10 nm.

23. The method of claim 18, wherein the hollow particles have a particle size distribution mean of between about 10-100 nm.

24. A coated article including a coating supported by a glass substrate, the coating comprising:
a combustion deposition deposited growth being grown such that the growth comprises a metal oxide matrix including hollow metal oxide particles embedded and/or implanted within a metal oxide binding layer, the hollow metal oxide particles being deposited from an atomized emulsion including at least aqueous and oil phases.

25. The coated article of claim 24, wherein the binding layer has a particle size distribution mean less than about 10 nm, and wherein the hollow metal oxide particles have a particle size distribution mean of between about 10-100 nm.

26. The coated article of claim 23, wherein the coating is a composite coating including at least two different metal oxides.

27. A method of making a coated article including a coating supported by a glass substrate, the method comprising:
forming a film comprising a metal oxide matrix having hollow metal oxide particles embedded and/or implanted therein,
wherein the metal oxide matrix is formed directly or indirectly on the substrate by combustion deposition depositing, via an emulsion including a first precursor contained in an aqueous and/or oil phase thereof, a first combusted material so as to deposit the hollow metal oxide particles, while also combustion deposition depositing, via a second metal oxide precursor, a second combusted material that would produce small nucleation particle size distributions if coated independently.
